(19) United States
(12) Patent Application Publication
(10) Pub. No.: US 2009/0233430 A1
(43) Pub. Date: Sep. 17, 2009

(54) SEMICONDUCTOR DEVICE MANUFACTURING METHOD, SEMICONDUCTOR DEVICE MANUFACTURING APPARATUS, AND SEMICONDUCTOR DEVICE MANUFACTURING SYSTEM

(75) Inventor: Akito HIRANO, Toyama-shi (JP)

Correspondence Address: BRUNDIDGE & STANGER, P.C., 1700 DIAGONAL ROAD, SUITE 330, ALEXANDRIA, VA, 22314, US

(73) Assignee: Hitachi-Kokusai Electric In.

(21) Appl. No.: 12/388,286

(22) Filed: Feb. 18, 2009

(30) Foreign Application Priority Data
Feb. 19, 2008 (JP) 2008-037821
Nov. 5, 2008 (JP) 2008-284646
Feb. 17, 2009 (JP) 2009-033493

(51) Int. Cl. H01L 21/283

(52) U.S. Cl. 438/591; 118/723 R; 257/E21.159

(57) ABSTRACT

Provided is a method of forming a high-k gate insulating film to reduce nitrogen leakage and suppress gate leakage current. A method of manufacturing a semiconductor device comprises: forming a high-k gate insulating film on a silicon substrate in a first process unit; carrying the silicon substrate to a second process unit; nitrogenizing the high-k gate insulating film using gas comprising nitrogen gas and rare gas; and annealing the silicon substrate in the second process unit.

### CROSS-REFERENCE TO RELATED PATENT APPLICATION

This U.S. non-provisional patent application claims priority under 35 U.S.C. § 119 of Japanese Patent Application Nos. 2008-037821, filed on Feb. 19, 2008, 2008-284646, filed on Nov. 5, 2008, and 2009-033493, filed on Feb. 17, 2009, in the Japanese Patent Office, the entire contents of which are hereby incorporated by reference.

### BACKGROUND OF THE INVENTION

1. Field of the Invention

The present invention relates to a semiconductor device manufacturing method, a substrate processing apparatus, and a substrate processing system for manufacturing a semiconductor device and forming a high-dielectric gate insulating film (hereinafter, referred to as a high-k gate insulating film) on a substrate, and more particularly, to improved technology for nitrogenizing a high-k gate insulating film.

2. Description of the Prior Art

With the development of highly-integrated, high speed semiconductor devices in theses days, there has been advance in miniaturization of metal oxide semiconductor field effect transistors (MOSFETs). However, in the case where the thickness of a gate insulating film becomes thinner as a result of the miniaturization of MOSFETs, a large gate leakage current flows through the gate insulating film hitherto made of an silicon oxide (SiO₂) due to the tunneling effect or other reasons. Particularly, unlike a capacitor insulating film, the gate insulating film required to be thin does not function as an insulating film if a large leakage current flows through the gate insulating film, and thus it is necessary to suppress the leakage current of the gate insulating film. For these reasons, as a method of suppressing gate leakage current, the physical thickness of the gate insulating film is increased while maintaining the equivalent oxide thickness of the gate insulating film at a low level by forming the gate insulating film using a high-k material such as hafnium oxide (HfO₂) or hafnium silicate (HfSiOₓ).

However, a high-k film such as a HfO₂ or HfSiOₓ film is crystallized by a heat treatment at about 700° C. If such a high-k film made of HfO₂ or HfSiOₓ is directly used as a gate insulating film after a film forming process, since the gate insulating film is heated to 1000° C. or more in a later annealing process, the crystal structure of HfO₂ or HfSiOₓ may be changed from amorphous to polycrystalline. Since crystal grain boundaries always exist in the polycrystalline structure, leakage current increases along defects of the crystal grain boundaries when a voltage is applied to a gate electrode.

Therefore, in a method proposed to prevent crystallization, a high-k gate insulating film is nitrogenized. If a high-k gate insulating film is nitrogenized, the degree of bond between the high-k gate insulating film and nitrogen is increased so that crystallization of the high-k gate insulating film can be suppressed. In the past, a thermal nitrogenizing method using nitrogen-containing gas such as ammonia gas (NH₃) was commonly used to introduce nitrogen into a gate insulating film; in recent days, however, a plasma nitrogenizing method using nitrogen gas has been favored (For example, refer to Patent Document 1).

In the plasma nitrogenizing method, elemental nitrogen gas (N₂) is activated through a plasma process to obtain an activated nitrogen species, and a bias voltage is applied to a silicon substrate to introduce the activated nitrogen species into a high-k gate insulating film formed on the silicon substrate. Unlike the plasma nitrogenizing method, the thermal nitrogenizing method is performed at a high temperature close to 1000° C. If a high-k gate insulating film is processed at a high temperature. crystallization occurs in the high-k gate insulating film. As described above, crystallization increases current leakage.

However, the plasma nitrogenizing method is performed at a lower temperature than the thermal nitrogenizing method. Therefore, a high-k gate insulating film is less crystallized when it is nitrogenized by plasma than when it is crystallized by heat.

Therefore, current leakage can be suppressed more effectively when a high-k gate insulating film is nitrogenized by plasma than when the high-k gate insulating film is nitrogenized by heat.

[Patent Document 1] Japanese Unexamined Patent Application Publication No. 2005-57163

However, the plasma nitrogenizing method has the following disadvantages.

The amount of nitrogen escaping from a gate insulating film should be small as compared with the amount of nitrogen escaping from a capacitor.

It is not necessary to strictly control the amount of nitrogen escaping from a device such as a capacity; however, the amount of nitrogen escaping from a gate insulating film should be strictly controlled for suppressing current leakage or increasing electric permittivity.

However, in a plasma nitrogenizing process using only nitrogen gas, a large portion of nitrogen, once introduced into a high-k gate insulating film, escapes from the high-k gate insulating film. Therefore, it is difficult to introduce a sufficient amount of nitrogen into the high-k gate insulating film for suppressing crystallization of the high-k gate insulating film.

In addition, since a silicon substrate is heated in a post nitridation anneal (post nitrogenization anneal, PNA) process after the plasma nitrogenizing process, a large amount of nitrogen escapes from the high-k gate insulating film during the PNA process. Therefore, in the case where a high-k gate insulating film is plasma-nitrogenized by only using nitrogen gas, it is more difficult to keep a sufficient amount of nitrogen in the high-k gate insulating film for suppressing crystallization of the high-k gate insulating film. As a result, it is difficult to suppress a large gate leakage current flowing to a gate electrode through the high-k gate insulating film.

### SUMMARY OF THE INVENTION

An object of the present invention is to provide a semiconductor device manufacturing method, a substrate processing apparatus, and a substrate processing system for forming a high-k gate insulating film adapted to suppress nitrogen leakage and gate leakage current.

According to an aspect of the present invention, there is provided a method of manufacturing a semiconductor device, the method comprising: forming a high-k gate insulating film on a silicon substrate in a first process unit; carrying the silicon substrate to a second process unit; nitrogenizing the high-k gate insulating film using gas comprising nitrogen gas and rare gas; and annealing the silicon substrate in the second process unit.

According to another aspect of the present invention, there is provided a system for manufacturing a semiconductor device, the system comprising: a first processing unit configured to form a high-k gate insulating film on a silicon substrate; a second processing unit configured to nitrogenize the high-k gate insulating film using gas comprising nitrogen gas and rare gas and anneal the silicon substrate; a third processing unit configured to form an electrode on the high-k gate insulating film; a fourth processing unit configured to form an insulating layer enclosing the electrode; and a substrate carrying unit configured to carry the substrate among the processing units.

According to another aspect of the present invention, there is provided a semiconductor device manufacturing apparatus for nitrogenizing a high-k gate insulating film formed on a silicon substrate, the semiconductor device manufacturing apparatus comprising: a reaction gas introduction unit configured to introduce reaction gas comprising nitrogen gas and rare gas into a substrate process chamber; a plasma generating unit configured to ionize the reaction gas into plasma; a substrate stage installed inside the process chamber for placing a substrate on the substrate stage; a substrate heating unit configured to heat a substrate; and a control unit configured to control an operation of introducing reaction gas comprising nitrogen gas and rare gas after a substrate comprising a high-k gate insulating film is carried into the process chamber, an operation of ionizing the introduced reaction gas into plasma for nitrogenizing the high-k gate insulating film of the substrate, and an operation of stopping introduction of the rare gas.

### BRIEF DESCRIPTION OF THE DRAWINGS

FIG. 1 is a schematic view illustrating a modified magnetron typed (MMT) apparatus as a substrate processing apparatus relevant to a first embodiment of the present invention.

FIG. 2 is a view for explaining a method of manufacturing a semiconductor device relevant to the first embodiment of the present invention.

FIG. 3 is a nitrogen concentration table, in which nitrogen concentrations in a HfSiOₓ film after a plasma nitrogenizing process at 400° C. and a PNA process are compared for the cases of using different reaction gases.

FIG. 4 is a nitrogen concentration table, in which nitrogen concentrations in a HfSiOₓ film after a plasma nitrogenizing process at 200° C. and a PNA process are compared.

FIG. 5 is a schematic view illustrating an inductively coupled plasma (ICP) processing apparatus as a substrate processing apparatus relevant to a second embodiment of the present invention.

FIG. 6 is a schematic view illustrating an electron cyclotron resonance (ECR) plasma processing apparatus as a substrate processing apparatus relevant to a third embodiment of the present invention.

FIG. 7 is a schematic view illustrating a cluster apparatus according to the present invention.

### DETAILED DESCRIPTION OF THE PREFERRED EMBODIMENTS

Explanation will now be given on an exemplary method of manufacturing a semiconductor device using a high-k gate insulating film.

According to the present invention, a high-k gate insulating film is plasma-nitrogenized using a mixture of nitrogen gas and rare gas. Therefore, as compared with a plasma nitrogenizing process using only nitrogen gas, the degree of bond between nitrogen and the high-k gate insulating film can be increased, and thus escaping of nitrogen from the high-k gate insulating film can be reduced. As a result, crystallization of the high-k gate insulating film can be suppressed although the high-k gate insulating film is treated at a high temperature, and thus gate current leakage can be suppressed.

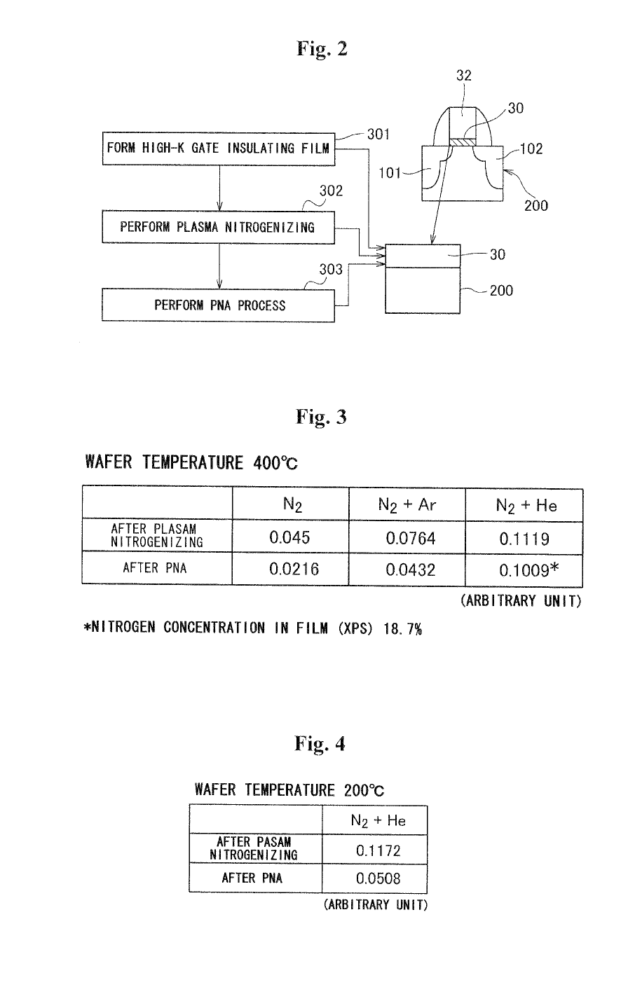

An embodiment of the present invention will be described hereinafter with reference to FIG. 2.

As shown in FIG. 2, a semiconductor device to be treated is a metal oxide semiconductor field effect transistor (MOSFET). The MOSFET includes a source 101 and a drain 102 formed in a silicon substrate (silicon wafer) 200, a high-k gate insulating film 30 formed between the source 101 and the drain 102, and a polysilicon electrode 32 formed on the high-k gate insulating film 30.

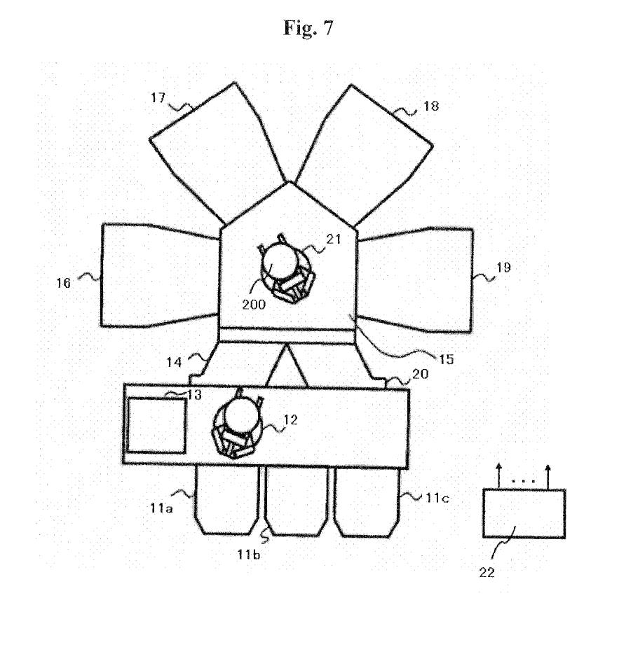

In the current embodiment, formation of the high-k gate insulating film 30, nitrogenization of the high-k gate insulating film 30, annealing of the nitrogenized high-k gate insulating film 30, and formation of the polysilicon electrode 32 after the annealing are performed using a semiconductor device manufacturing system such as a cluster apparatus shown in FIG. 7. The cluster apparatus of FIG. 7 includes carrier stations 11a, 11b, and 11c (load ports), an atmospheric transport unit 12, a substrate position correction unit 13, a loadlock chamber 14, a carrying chamber 15 at which a vacuum transfer unit 21 (substrate carrying unit) is installed, a first process unit 16, a second process unit 17, a third process unit 18, and a fourth process unit 19. The process units 16 to 19 are controlled by a controller 22. The process units 16 to 19 will be described later.

Hereinafter, a detailed explanation will be given on the flow of processes performed using the cluster apparatus. In the following explanation, operations of parts of the cluster apparatus are controlled by the controller 22 (control unit).

To form a high-k gate insulating film 30 on the surface of a wafer 200, the wafer 200 is loaded into the first process unit 16 used as a high-k film forming apparatus by the substrate carrying unit 21. In the high-k film forming apparatus 16, according to a predetermined film forming method such as poly-atomic layer chemical vapor deposition (PLCVD) method, remote plasma oxygen or ozone (O₃), and an organic metallic material containing hafnium (Hf) or silicon (Si) are introduced to the surface of the wafer 200 to form a metal oxide film such as a HfO₂ or HfSiOₓ film as the high-k gate insulating film 30 (step 301).

After the high-k gate insulating film 30 is formed, the wafer 200 is loaded into the second process unit 17 (MMT apparatus) by the substrate carrying unit 21. The MMT apparatus 17 will be described later in detail. In the MMT apparatus 17, the high-k gate insulating film 30 is nitrogenized (step 302).

After the nitrogenization, the wafer 200 is loaded into the third process unit 18 (rapid thermal processing (RTP) apparatus) by the substrate carrying unit 21. In the RTP apparatus 18, the nitrogenized high-k gate insulating film 30 of the wafer 200 is annealed. Through the annealing, the bond strength between the high-k gate insulating film 30 and nitrogen can be increased, and thus current leakage can be prevented more efficiently (step 303).

After the annealing, the wafer 200 is carried to the fourth process unit 19 (electrode forming apparatus) by the substrate carrying unit 21. A gate electrode 32 (polysilicon electrode) is formed on the nitrogenized and annealed high-k gate insulating film 30.

After the polysilicon electrode 32 is formed, the wafer 200 is carried from the cluster apparatus to an insulating layer forming apparatus. In the insulating layer forming apparatus, an insulating layer 34 is formed using a material such as silicon nitride (Si₃N₄) to cover the polysilicon electrode 32. The insulating layer 34 may be formed by a chemical vapor deposition (CVD) method using SiH₂Cl₂ gas and NH₃ gas.

After the insulating layer 34, the wafer 200 is loaded into an ion implanting apparatus, and a source 101 and a drain 102 (impurity regions) are formed using a method such as an ion implanting method by adding an n-type impurity to a main surface of the wafer 200. Between the source 101 and the drain 102, a channel 103 is formed.

In this way, the gate part of a semiconductor device is formed.

In the system or between the apparatuses, a substrate is carried using one or more carrying devices.

Next, a modified magnetron typed (MMT) apparatus will be described as a substrate processing apparatus (nitrogenizing apparatus) for nitrogenizing a high-k gate insulating film according to the present invention.

In an embodiment of the present invention, a plasma processing furnace is a substrate processing furnace configured to process a substrate such as a wafer using an MMT plasma source, which is provided for generating high-density plasma using electric and magnetic fields (hereinafter, the plasma processing furnace will be referred as an MMT apparatus). In the MMT apparatus, a substrate is loaded in an air-tightly sealed process chamber; reaction gas is introduced into the process chamber through a shower head; and while maintaining the process chamber at a predetermined pressure, high-frequency power is supplied to a discharge electrode to generate an electric field and a magnetic field at the same time for magnetron discharging. Electrons emitted from the discharge electrode revolve while continuing cycloidal drifting so that the electrodes exist for a long time. Therefore, the rate of ionization can be increased, and thus high-density plasma can be generated. In this way, reaction gas can be activated or decomposed to perform various plasma processes on a substrate, such as a diffusion process (e.g., diffusion oxidization and diffusion nitrogenizing) a thin film forming process, and an etching process.

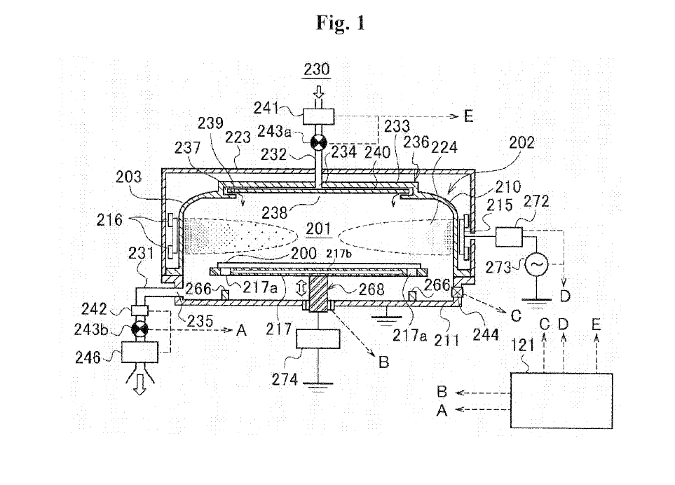

FIG. 1 is a schematic view illustrating such an MMT apparatus as a substrate processing apparatus relevant to a first embodiment of the present invention.

The MMT apparatus includes a process vessel 203, and the process vessel 203 includes a dome-shaped upper vessel 210 as a first vessel and a bowl-shaped lower vessel 211 as a second vessel. The upper vessel 210 covers the upper side of the lower vessel 211. The upper vessel 210 is made of an aluminum oxide or a nonmetallic material such as quartz, and the lower vessel 211 is made of quartz. In addition, a susceptor 217 (described later) used as a substrate holder (substrate holding unit) integrated with a heater 217b is made of an aluminum nitride, or a nonmetallic material such as a ceramic material or quartz, so as to prevent contamination of a film during a process.

A shower head 236 is installed at an upper side of a process chamber 201. The shower head 236 includes a cap-shaped cover 233, a gas inlet 234, a buffer chamber 237, an opening 238, a shield plate 240, and a gas blow outlet 239. The buffer chamber 237 provides a space for dispersing gas introduced through the gas inlet 234.

A gas introduction pipe 232 is connected to the gas inlet 234, and a gas cylinder (not shown) in which a reaction gas 230 is stored is connected to the gas introduction pipe 232 through an on-off valve 243a and a mass flow controller 241 used as a flow rate controller.

A reaction gas 230 is introduced to the process chamber 201 through the shower head 236 (reaction gas introduction unit),. and a gas exhaust outlet 235 is installed at a sidewall of the lower vessel 211 to allow the reaction gas 230 to flow from the vicinity of the susceptor 217 to the bottom side of the process chamber 201 after the reaction gas 230 is used for processing a substrate. A gas exhaust pipe 231 is connected to the gas exhaust outlet 235 for exhausting gas, and a vacuum pump 246 (exhaust device) is connected to the gas exhaust pipe 231 through an automatic pressure control (APC) valve 242 (pressure regulator) and an on-off valve 243b.

As a discharging structure (discharging unit or plasma generating unit) for exciting a reaction gas 230 into plasma, a tubular electrode 215 (first electrode) having a tubular shape such as a cylindrical shape is installed. The tubular electrode 215 is installed around the circumference of the process vessel 203 (the upper vessel 210) to surround a plasma generating region 224 defined inside the process chamber 201. A high-frequency power supply 273 is connected to the tubular electrode 215 through a matching device 272 used for impedance matching.

In addition, as magnetic field forming structures (magnetic field forming units), magnets 216 having a tubular shape such as a cylindrical shape and configured by permanent magnets are provided. The tubular magnets 216 are disposed close to upper and lower ends of the outer surface of the tubular electrode 215. The upper and lower tubular magnets 216 have magnetic poles at both ends (inner and outer circumferential ends) along a radial direction of the process chamber 201 with opposite poles of the upper and lower tubular magnets 216 being aligned with each other. That is, inner-circumferential magnetic poles having opposite polarities are aligned in a manner such that magnetic field lines exist along the inner circumference of the tubular electrode 215 in the center-axis direction of the tubular electrode 215.

At the lower center side of the process chamber 201, the susceptor 217 is installed as a substrate holder (substrate stage) for holding a substrate such as a wafer 200. The susceptor 217 is made of an aluminum nitride or a nonmetallic material such as a ceramic material or quartz, and the heater 217b is integrally buried in the susceptor 217 as a heating structure (substrate heating unit) for heating a wafer 200. The heater 217b is configured to heat a wafer 200 up to about 500° C. when power is supplied to the heater 217b. In the current embodiment, the heating unit has a structure buried in the susceptor 217. However, the present invention is not limited thereto. For example, a heater may be installed outside the process chamber 201 for heating a wafer. In another example, a heater may be installed inside the process chamber 201 away from the susceptor 217.

In addition, if the substrate processing apparatus is used as an RTP apparatus, the heater 217b is set to heat a wafer to about 1050° C. Alternatively, the heater 217b may be set to heat a wafer to about 500° C., and an additional RTP heater may be used; in this case, the heater 217b installed in the susceptor 217 and the RTP heater may be used together to heat the wafer. For example, in a wafer nitrogenizing process the heater 217b may heat a wafer to about 500° C., and then the heater 217b and the RTP heater may be used together to heat the wafer to about 1050° C. for annealing the wafer.

Inside the susceptor 217, a second electrode (not shown) is equipped to adjust impedance again. The second electrode is grounded via an impedance varying device 274. The impedance varying device 274 is configured by a coil or a variable condenser so that the potential of a wafer 200 can be controlled via the second electrode and the susceptor 217 by varying the number of patterns of the coil or the capacitance of the variable condenser.

A process furnace 202 configured to process a wafer 200 by magnetron-discharging of a magnetron type plasma source is constituted by at least the process chamber 201, the process vessel 203, the susceptor 217, the tubular electrode 215, the tubular magnets 216, the shower head 236, and the gas exhaust outlet 235. In the process chamber 201, a wafer 200 can be treated using plasma.

Around the tubular electrode 215 and the tubular magnets 216, a shield plate 223 is installed to prevent electric and magnetic fields formed by the tubular electrode 215 and the tubular magnets 216 from affecting outside environments or other apparatuses such as other furnaces.

The susceptor 217 is insulated from the lower vessel 211, and a susceptor elevating mechanism (elevating unit) 268 is installed to move the susceptor 217 upward and downward. Penetration holes 217a are formed through the susceptor 217, and wafer lifting pins 266 are installed at at least three positions of the bottom surface of the lower vessel 211 for lifting a wafer 200. The penetration holes 217a and the wafer lifting pins 266 are arranged in a manner such that the wafer lifting pins 266 can pass through the penetration holes 217a without making contact with the susceptor 217 when the susceptor 217 is moved downward by the susceptor elevating mechanism 268.

At the sidewall of the lower vessel 211, a gate valve 244 is installed. The gate valve 244 can be opened to load/unload a wafer 200 into/from the process chamber 201 by using the substrate carrying unit 21, and the gate valve 244 can be closed to make the process chamber 201 airtight.

A controller 121 is used as a control part (control unit) for controlling the APC valve 242, the on-off valve 243a, the vacuum pump 246 via a signal line A; the susceptor elevating mechanism 268 via a signal line B; the gate valve 244 via a signal line C; the matching device 272 and the high-frequency power supply 273 via a signal line D; the mass flow controller 241 and the on-off valve 243a via a signal line E; and the heater 217b buried in the susceptor 217 and the impedance varying device 274 via a signal line (not shown).

Next, an explanation will be given on a method of nitrogenizing a high-k gate insulating film using the MMT apparatus 17. In the following explanation, parts of the MMT apparatus 17 are controlled by the controller 121.

After a high-k gate insulating film 30 is formed on a wafer 200, the wafer 200 is carried from the high-k film forming apparatus 16 to the MMT apparatus illustrated FIG. 1 by the substrate carrying unit 21.

By the substrate carrying unit 21, the wafer 200 is carried from the outside of the process chamber 201 constituting the process furnace 202 into the process chamber 201 and is loaded on the susceptor 217. The wafer 200 loaded on the susceptor 217 is a silicon wafer on which a high-k gate insulating film such as a HfO₂ or HfSiOₓ film is formed. In some cases, a HfSiOₓ film may be layered between the surface of a silicon wafer and an HfO₂ film.

In detail, the wafer 200 is carried as follows. When the susceptor 217 is moved down to a wafer receiving position, the wafer lifting pins 266 passes through the penetration holes 217a of the susceptor 217. At this time, the wafer lifting pins 266 protrude from the surface of the susceptor 217 by a predetermined length. Next, the gate valve 244 installed at the lower vessel 211 is opened, and the carrying unit 21 places the wafer 200 on ends of the wafer lifting pins 266. Then, after the carrying unit 21 is moved to the outside of the process chamber 201, the gate valve 244 is closed. Thereafter, the susceptor 217 is moved upward by the susceptor elevating mechanism 268 so that the wafer 200 can be placed on the surface of the susceptor 217 and moved upward to a processing position.

The heater 217b buried in the susceptor 217 is previously operated, and the wafer 200 is heated by the heater 217b to a predetermined wafer processing temperature in the range from 200° C. to 500° C.

At this time the heater 217b is controlled such that the wafer 200 can be kept at a temperature equal to or higher than 200° C. but lower than 500° C.

By performing a nitrogenizing process using plasma at a temperature equal to or higher than 200° C. but lower than 500° C,, the bond strength between the high-k gate insulating film 30 and nitrogen can be increased. Therefore, less nitrogen escapes from the high-k gate insulating film 30 in a post nitridation anneal (post nitrogenization anneal, PNA) process, and thus crystallization and current leakage can be suppressed more surely.

The temperature of the nitrogenizing process is kept lower than 500° C. If the temperature is equal to or higher than 500° C., the mobility of an MOSFET is lowered due to thermal diffusion of nitrogen to interfacial silicon (Si). In addition, gate leak current increases due to crystallization at a high temperature. Therefore, it is preferable that the temperature of the nitrogenizing process be kept equal to or higher than 200° C. but lower than 500° C.

In addition, it is more preferable that the temperature of a wafer be kept equal to or higher than 300° C. but lower than 500° C., particularly, at about 400° C. If the temperature of the wafer is kept equal to or higher than 300° C., the amount of escaping nitrogen can be significantly reduced as compared with the case where the temperature of the wafer is kept equal to or higher than 200° C. but lower than 300° C.

After the wafer 200 reaches the predetermined processing temperature and is stably maintained at the predetermined processing temperature, a previously prepared mixture of nitrogen gas and rare gas is introduced from the gas inlet 234 to the top surface (processing surface) of the wafer 200 disposed in the process chamber 201 through the gas blow outlet 239 of the shield plate 240. At this time, the gas mixture is introduced at a predetermined flow rate. The rare gas may be argon (Ar) or helium (He). When the rare gas is added to nitrogen gas, the amount of nitrogen gas may be increased according to the amount of the added rare gas.

The process chamber 201 is maintained at a predetermined pressure in the range from 1 Pa to 10 Pa by using the vacuum pump 246 and the APC valve 242.

While maintaining the process chamber 201 at the predetermined pressure, high-frequency power is applied to the tubular electrode 215 from the high-frequency power supply 273 through the matching device 272. The high-frequency power applied to the tubular electrode 215 has a predetermined level in the range from 300 W to 700 W. At this time, a desired impedance valve can be obtained by previously adjusting the impedance varying device 274. By this bias adjustment, the energy of plasma incident on the wafer 200 can be controlled.

Owing to a magnetic field formed by the tubular magnets 216, 216, magnetron discharging occurs, and electric charge is trapped above the wafer 200, so that the mixture of nitrogen gas and rare gas can be ionized into high-density plasma. The high-density plasma produces an activated nitrogen species. The high-k gate insulating film 30 formed on the wafer 200 is plasma-nitrogenized using the activated nitrogen species to introduce nitrogen into the high-k gate insulating film 30 (refer to step 302 of FIG. 2).

The gas mixture is introduced at a nitrogen gas: rare gas flow rate ratio of 1:9 to 1:19. In this condition, high-concentration nitrogenization is possible. The activated nitrogen species produced from the high-density plasma can be controlled using the impedance varying device 274 capable of adjusting the energy of ions entering into the wafer 200 placed on the susceptor 217, so as to control the depth profile of nitrogen introduced into the high-k gate insulating film 30.

After the plasma nitrogenizing process, introduction of rare gas is interrupted, and nearly at the same time, magnetron discharging stops. Then, the inside atmosphere of the process chamber 201 is only nitrogen (N₂) gas.

The wafer 200 treated by plasma nitrogenizing is carried out from the process chamber 201 using the carrying unit 21 in the reverse order to the carrying-in order.

The wafer 200 carried out from the process chamber 201 after the plasma nitrogenizing process is carried to an annealing apparatus. For example, the annealing apparatus may be an RTP apparatus. The RTP apparatus is a rapid heating device using, for example, a lamp. While the temperature of the wafer 200 is feedback controlled using temperature information measured at a side of the wafer 200 by a temperature probe, the wafer 200 is heated using a lamp disposed at the other side of the wafer 200. Power to the lamp is controlled so that each surface zone of the wafer 200 can be uniformly heated for uniform temperature distribution, and moreover the wafer 200 is rotated by a rotary mechanism while the wafer 200 is heated for further improving the temperature distribution uniformity.

In the RTP apparatus, a PNA process is performed on the wafer 200 to enhance the degree of bond between the high-k gate insulating film 30 and nitrogen.

Instead of carrying the wafer 200 from the MMT apparatus to another process chamber after the nitrogenizing process, the wafer 200 may be processed by PNA in the MMT apparatus.

In this case, introduction of rare gas used for the nitrogenizing process is first stopped. At approximately the same time, magnetron discharging is stopped. Introduction of nitrogen is continued from the nitrogenizing process. Therefore, the inside of the process chamber 201 can be filled with only N₂. In this nitrogen atmosphere, the wafer 200 placed in the process chamber 201 is continuously heated by the heater 217b.

Nitrogen introduced into the high-k gate insulating film 30 may be released from the high-k gate insulating film 30 with the lapse of time. However, as described above, in the case where the PNA process is performed on the wafer 200 in the same process chamber without moving the wafer 200 to another process chamber after the nitrogenizing process, more nitrogen couples to the high-k gate insulating film 30 and remains in the high-k gate insulating film 30.

Particularly, in the case where the annealing process is performed in the same process chamber after the nitrogenizing process, time necessary for initializing the annealing process can be reduced, and thus the amount of nitrogen escaping from the high-k gate insulating film 30 can be efficiently reduced.

Furthermore, in this case, since the wafer 200 is not moved in the process chamber 201, the processed wafer 200 can be less contaminated.

(Refer to step 303 of FIG. 2)

After the annealing process, the wafer 200 is carried out from the process chamber by the carrying unit 21 in the reverse order to the carrying-in order.

Next, a specific example of the nitrogenizing process will be described.

A plasma nitrogenizing process was performed using the MMT apparatus illustrated in FIG. 1.

As shown in FIG. 3 and FIG. 4, a plurality of gas mixtures was used.

Experiments were conducted while varying reaction gas introduced into the process chamber of the MMT apparatus from nitrogen gas (N₂), mixture gas of N₂ and Ar, to mixture gas of N₂ and He. HfSiOₓ gate insulting films formed on silicon wafers were plasma-nitrogenized using the reaction gases, respectively.

The experiment with (N₂+He) mixture gas was performed at a wafer temperature of 200° C. and at a wafer temperature of 400° C., and both the experiment with N₂ gas and the experiment with (N₂+Ar) mixture gas were performed at a wafer temperature of 400° C.

Other experimental conditions of the process chamber are as follows: pressure is 1 pa to 10 pa, radio frequency (RF) power is 300 W to 700 W, N₂:Ar flow rate ratio is 1:9 to 1:19, and N₂:H2 flow rate ratio is 1:9 to 1:19.

After the plasma nitrogenizing processes, the wafers were not moved to another process chamber, and PNA processes were performed on the wafers. The PNA processes were performed in the process chamber under a nitrogen atmosphere at a wafer temperature of 1050° C. during 10 seconds.

Referring to FIG. 3, nitrogen concentrations in high-k gate insulating films were measured by X-ray photoelectron spectroscopy (XPS) after the high-k gate insulating films were treated by plasma nitrogenization at a wafer temperature of 400° C. using different reaction gases and after the PNA processes were performed on the high-k gate insulating films, so as to compare relative nitrogen atom amounts contained in the high-k gate insulating films. As shown in FIG. 3, when the nitrogen atom amounts are compared for different reaction gases, the nitrogen atom amounts increase in terms of reaction gases as follows: N₂<(N₂+Ar)<(N₂+He). Particularly, when helium (He) is used as rare gas, the nitrogen gas amount is large. In the case where (N₂+He) mixture gas is used for plasma nitrogenizing, the nitrogen concentration (XPS) in the high-k gate insulating film approaches 15% after a PNA process. That is, the nitrogen concentration approaches to a higher level than the cases where only N₂ gas or (N₂+Ar) mixture gas are used for plasma nitrogenizing.

Referring to FIG. 4, nitrogen concentrations in the high-k gate insulating film were measured by XPS after the high-k gate insulating film was treated by plasma nitrogenizing at a wafer temperature of 200° C. using (N₂+He) mixture as a reaction gas and after the PNA process was performed on the high-k gate insulating film, so as to compare relative nitrogen atom amounts contained in the high-k gate insulating film. As shown in FIG. 4 and FIG. 3, if the nitrogenizing temperature is low in the case of using (N₂+He) mixture gas as a reaction gas, nitrogen leakage is large during a PNA process.

The above-described embodiments provide a semiconductor device manufacturing method including a process of forming a high-k gate insulating film on a substrate and a process of performing a plasma nitrogenizing process on the high-k gate insulating film by using a mixture of nitrogen gas and rare gas. According to the embodiments, one or more of the following effects can be attained.

(1) Since a plasma nitrogenizing process is performed using a mixture of nitrogen gas and rare gas, the amount of nitrogen escaping from a high-k gate insulating film can be reduced as compared with the case of performing a simple nitrogenizing process. Therefore, increase of gate leakage current can be surely prevented.

(2) An activated nitrogen species produced from plasma is introduced into a high-k gate insulating film in a way that hydrogen (H) of Si-OH bonds of the high-k gate insulating film is replaced with the activated nitrogen species, so that the nitrogen concentration in the high-k gate insulating film can be increased.

(3) An activated nitrogen species produced from plasma of a nitrogen and rare gas mixture is used to introduce nitrogen into a high-k gate insulating film formed on a silicon wafer using HfO₂ or HfSOₓ. In this case, the energy of ionized rare gas having a higher ionization potential is transferred to nitrogen molecules (this is known as Penning effect), so that an activated nitrogen species can be produced more efficiently, and more nitrogen can be introduced into the high-k gate insulating film. In addition, since the high-k gate insulating film is treated using plasma, the bond between the high-k gate insulating film and nitrogen can be enhanced so that the amount of nitrogen leaking (escaping) from the high-k gate insulating film can be reduced in a later PNA process. Therefore, a sufficient amount of nitrogen can be ensured.

Accordingly, crystallization of the high-k gate insulating film can be sufficiently suppressed, and thus an increase of gate leakage current caused by crystal grain boundaries can be surely prevented.

(4) Nitrogen leakage can be largely reduced by using helium (He) as compared with the case of using other rare gas such as argon (Ar).

(5) Performing a plasma nitrogenizing process at a temperature of 300° C. to 500° C. is advantageous in that: the bond between a high-k gate insulating film and nitrogen can be enhanced; nitrogen leakage can be reduced in a later PNA process; crystallization of the high-k gate insulating film can be surely suppressed; and current leakage through the gate insulating film can be surely suppressed. If the plasma nitrogenizing process is performed at a temperature lower than 300° C., specific permittivity cannot be improved due to nitrogen leakage. Furthermore, gate leakage current through the high-k gate insulating film cannot be reduced, or heat resistance of the high-k gate insulating film cannot be improved in a later process. In addition, nitrogen leakage in a PNA process increases. Therefore, it is preferable that the plasma nitrogenizing process be performed at a temperature of 300° C. or higher. However, the plasma nitrogenizing process may not be performed at 500° C. or higher. If the plasma nitrogenizing process is performed at 500° C. or higher, thermal diffusion of nitrogen can reach an interfacial silicon (Si) to reduce MOSFET mobility. Furthermore, the high-k gate insulating film can be crystallized at such a high temperature, and thus gate leakage current can be increased. Therefore, it is preferable that the plasma nitrogenizing process be performed at 300° C. to 500° C.

(6) In addition, the degree of bond between a high-k gate insulating film and nitrogen can be increased after a PNA process is performed on the high-k gate insulating film. Therefore, gate leakage current can be suppressed more reliably.

(7) Furthermore, in the MMT apparatus, the energy of plasma incident on a wafer can be adjusted by bias controlling. Therefore, when a high-k gate insulating film made of a material such as HfO₂ and HfSiOₓ is nitrogenized using plasma, the profile and amount of nitrogen introduced into the high-k gate insulating film can be easily controlled. This allows high-density nitrogenizing and nitrogen profile controlling, and thus crystallization of the high-k gate insulating film can be effectively suppressed by the plasma nitrogenizing process. Therefore, gate leakage current can be suppressed more surely.

In the above-described embodiments. an MMT apparatus is used for performing a plasma nitrogenizing process. However, the present invention is not limited to the MMT apparatus. For example, other apparatuses such as an inductively coupled plasma (ICP) apparatus and an electron cyclotron resonance (ECR) apparatus may be used.

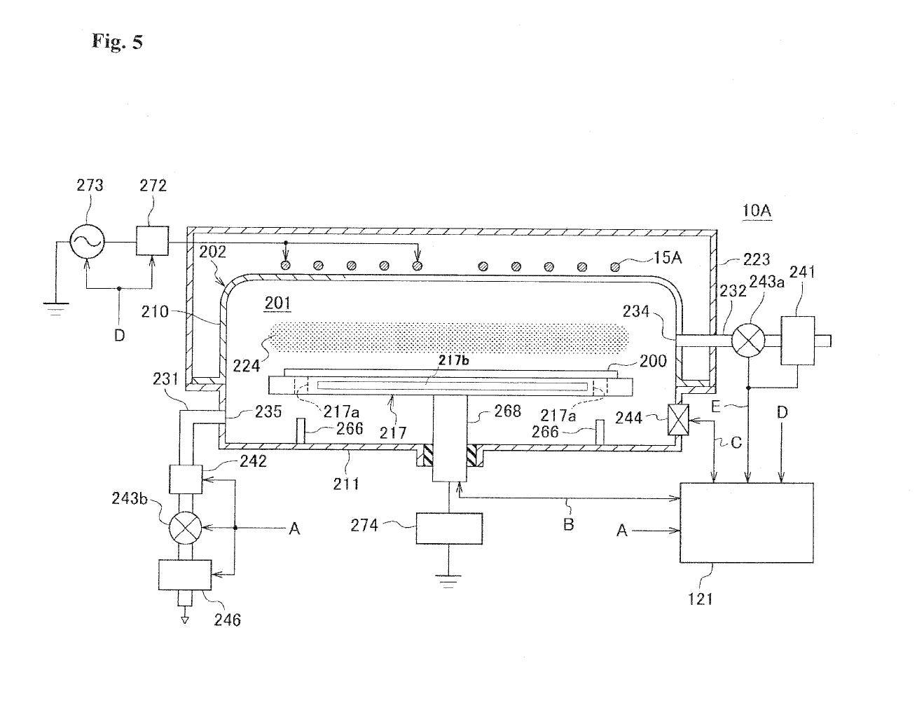

FIG. 5 is a schematic view illustrating ICP processing apparatus as a substrate processing apparatus relevant to a second embodiment of the present invention. In the description of the current embodiment, elements having the same functions as the elements of the first embodiment will be denoted by the same reference numerals, and descriptions of the elements having the same functions will be omitted.

The ICP processing apparatus 10A of the current embodiment includes an induction coil 15A as a plasma generating unit for generating plasma using electricity, and the induction coil 15A is installed at the outside of a ceiling wall of a process vessel 202. In the current embodiment, a mixture of nitrogen gas and rare gas is introduced to the process vessel 202 from a gas introduction pipe 232 through a gas blow outlet 234, like in the previous embodiment. Before or after the introduction of the gas mixture, high-frequency power is supplied to the induction coil 15A used as a plasma generating unit to generate an electric field by electromagnetic induction. The introduced gas mixture is ionized into plasma by the energy of the electric field, and a high-k gate insulating film formed on a wafer 200 is nitrogenized by an activated nitrogen species produced from the plasma.

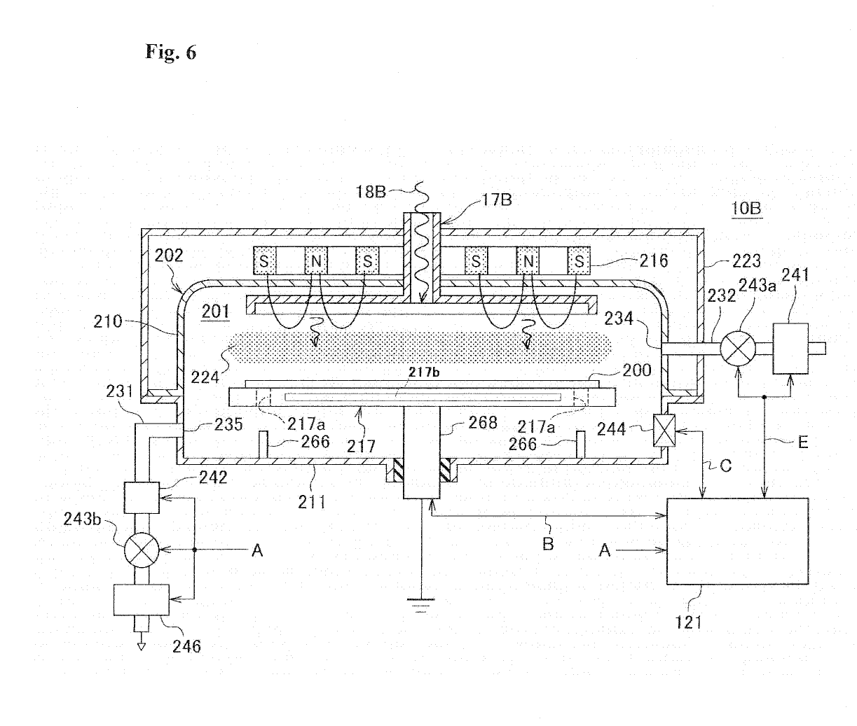

FIG. 6 is a schematic view illustrating an ECR plasma processing apparatus as a substrate processing apparatus relevant to a third embodiment of the present invention. In the description of the current embodiment, elements having the same functions as the elements of the previous embodiments will be denoted by the same reference numerals, and descriptions of the elements having the same functions will be omitted.

The ECR plasma processing apparatus 10B of the current embodiment includes a microwave guide pipe 17B as a plasma generating unit for generating plasma using microwaves. In the current embodiment, a mixture of nitrogen gas and rare gas is introduced to a process vessel 202 from a gas introduction pipe 232 through a gas blow outlet 234, like in the previous embodiments. Before or after the introduction of the gas mixture, microwaves 18B are introduced through the microwave guide pipe 17B into a process chamber 201. The introduced gas mixture is ionized into plasma by the microwaves 18B, and a high-k gate insulating film formed on a wafer 200 is nitrogenized by an activated nitrogen species produced from the plasma.

In the above-described embodiments, explanations are given on a method of heating a wafer using an RTP apparatus after the wafer is nitrogenized, and a method of heating a wafer in a second process chamber (MMT apparatus) after nitrogenization and post nitrogenization processes are performed on the wafer in the second process unit. However, the present invention is not limited to thereto.

For example, after a wafer is heated in a second process chamber, the wafer may be carried to an RTP apparatus and be heated in the RTP apparatus.

In this case, since the wafer is heated in the second process chamber (MMT apparatus), the bond between nitrogen and a high-k gate insulating film can be increased. In addition, since the wafer is heated to a high temperature in the RTP apparatus, more nitrogen can be coupled to the high-k gate insulating film, and thus current leakage can be suppressed more surely.

According to the present invention, a high-k gate insulating film can be formed, which makes nitrogen difficult to escape from the high-k gate insulating film and suppresses a gate leakage current flowing across the high-k gate insulating film.

(Supplementary Note)

The present invention also includes the following embodiments.

(Supplementary Note 1)

According to an embodiment of the present invention, there is provided a semiconductor device manufacturing method comprising performing a plasma nitrogenizing process on a high-k gate insulating film formed on a substrate by using a mixture of nitrogen gas and rare gas.

According to the method. one of the following effects or other effects can be attained. Since the plasma nitrogenizing process is performed using a mixture of nitrogen gas and rare gas, escaping of nitrogen from the high-k gate insulating film can be prevented more surely than the case of simple nitrogenization. Owing to this, crystallization can be suppressed, and gate leak current can be reduced. In addition, owing to the improved bond strength between nitrogen and the high-k gate insulating film, heat-resisting characteristics can be improved. Moreover, the relative permittivity of a gate insulating film can be high since the high-k gate insulating film is used as the gate insulating film.

(Supplementary Note 2)

In the semiconductor device manufacturing method of Supplementary Note 1, the rare gas may be helium (He).

In this case, escaping of nitrogen can be suppressed more surely than the case where other rare gas such as argon (Ar) is used.

(Supplementary Note 3)

In the semiconductor device manufacturing method of Supplementary Note 1, the plasma nitrogenizing process may be performed at a temperature equal to or higher than 300° C. but lower than 500° C.

It is preferable that the temperature of the plasma nitrogenizing process be equal to or higher than 300° C. but lower than 500° C. In this case, during a PNA process, less nitrogen escapes from the high-k gate insulating film, and crystallization of the high-k gate insulating film can be suppressed.

(Supplementary Note 4)

The semiconductor device manufacturing method of Supplementary Note 1 may further comprise performing an annealing process after the plasma nitrogenizing process.

In this case, the bond strength between nitrogen and the high-k gate insulating film can be increased, and thus gate leak current can be suppressed more surely.

(Supplementary Note 5)

According to another embodiment of the present invention, there is provided a substrate processing method comprising forming a metal oxide film containing nitrogen by performing a plasma nitrogenizing process on a high-k metal oxide film formed on a surface of a semiconductor substrate by using a mixture of nitrogen gas and helium gas.

(Supplementary Note 6)

In the semiconductor device manufacturing method of Supplementary Note 1, wherein the plasma nitrogenizing process may be performed at a pressure of 1 Pa to 10 Pa, RF power of 300 W to 700 W, a nitrogen gas:helium gas flow rate ratio of 1:9 to 1:19.

(Supplementary Note 7)

In the semiconductor device manufacturing method of Supplementary Note 1, wherein the plasma nitrogenizing process may be performed at a pressure of 1 Pa to 10 Pa, RF power of 300 W to 700 W. a nitrogen gas:argon gas flow rate ratio of 1:9 to 1:19.

(Supplementary Note 8)

According to an embodiment of the present invention, there is provided a method of manufacturing a semiconductor device, the method comprising: forming a high-k gate insulating film on a silicon substrate; nitrogenizing the high-k gate insulating film using gas comprising nitrogen gas and rare gas; forming an electrode on the high-k gate insulating film; and forming an insulating layer enclosing the electrode.

(Supplementary Note 9)

In the method of Supplementary Note 8, the rare gas may be helium (He).

(Supplementary Note 10)

The method of Supplementary Note 8 or 9 may further comprise performing a heat treatment on the substrate after the nitrogenizing of the high-k gate insulating film but prior to the forming of the electrode.

(Supplementary Note 11)

In the method of any one of Supplementary Notes 8 to 10, the nitrogenizing of the high-k gate insulating film may be performed while maintaining the substrate at a temperature of 200° C. to 500° C.

(Supplementary Note 12)

In the method of any one of Supplementary Notes 8 to 10, the nitrogenizing of the high-k gate insulating film may be performed while maintaining the substrate at a temperature equal to or higher than 300° C. but lower than 500° C.

(Supplementary Note 13)

According to another embodiment of the present invention, there is provided a system for manufacturing a semiconductor device, the system comprising: a first processing unit configured to form a high-k gate insulating film on a silicon substrate; a second processing unit configured to nitrogenize the high-k gate insulating film using gas comprising nitrogen gas and rare gas; a third processing unit configured to form an electrode on the high-k gate insulating film; a fourth processing unit configured to form an insulating layer enclosing the electrode; and a substrate carrying unit configured to carry the substrate among the processing units.

(Supplementary Note 14)

The system of Supplementary Note 13 may further comprise a substrate heating unit configured to perform a heat treatment after the high-k gate insulating film is nitrogenized.

(Supplementary Note 15)

According to another embodiment of the present invention, there is provided a semiconductor device manufacturing apparatus for nitrogenizing a high-k gate insulating film formed on a silicon substrate, the semiconductor device manufacturing apparatus comprising: a reaction gas introduction unit configured to introduce reaction gas comprising nitrogen gas and rare gas to a substrate process chamber; a plasma generating unit configured to ionize the reaction gas into plasma; a substrate stage installed inside the process chamber for placing a substrate on the substrate stage; a substrate heating unit configured to heat a substrate; and a control unit configured to control an operation of introducing reaction gas comprising nitrogen gas and rare gas after a substrate comprising a high-k gate insulating film is carried into the process chamber and an operation of ionizing the introduced reaction gas into plasma for nitrogenizing the high-k gate insulating film of the substrate.

(Supplementary Note 16)

In the semiconductor device manufacturing apparatus of Supplementary Note 15, the rare gas may be helium (He).

(Supplementary Note 17)

In the semiconductor device manufacturing apparatus of Supplementary Note 15 or 16, the control unit may stop the plasma generating unit after the high-k gate insulating film is nitrogenized, and then, the control unit may control the substrate heating unit to heat the substrate.

(Supplementary Note 18)

In the semiconductor device manufacturing apparatus of any one of Supplementary Notes 15 to 17, the control unit may control the substrate heating unit to maintain the substrate at a temperature equal to or higher than 200° C. but lower than 500° C. when the high-k gate insulating film of the substrate is nitrogenized.

(Supplementary Note 19)

In the semiconductor device manufacturing apparatus of any one of Supplementary Notes 15 to 17. the control unit may control the substrate heating unit to maintain the substrate at a temperature equal to or higher than 300° C. but lower than 500° C. when the high-k gate insulating film of the substrate is nitrogenized.

What is claimed is:

1. A method of manufacturing a semiconductor device, the method comprising:
forming a high-k gate insulating film on a silicon substrate in a first process unit;
carrying the silicon substrate to a second process unit;
nitrogenizing the high-k gate insulating film using gas comprising nitrogen gas and rare gas; and
annealing the silicon substrate in the second process unit.

2. The method of claim 1, wherein the rare gas is helium (He).

3. The method of claim 1, wherein the nitrogenizing of the high-k gate insulating film is performed while maintaining the substrate at a temperature equal to or higher than 200° C. but lower than 500° C.

4. A system for manufacturing a semiconductor device, the system comprising:
a first processing unit configured to form a high-k gate insulating film on a silicon substrate;
a second processing unit configured to nitrogenize the high-k gate insulating film using gas comprising nitrogen gas and rare gas and anneal the silicon substrate;
a third processing unit configured to form an electrode on the high-k gate insulating film;
a fourth processing unit configured to form an insulating layer enclosing the electrode; and
a substrate carrying unit configured to carry the substrate among the processing units.

5. A semiconductor device manufacturing apparatus for nitrogenizing a high-k gate insulating film formed on a silicon substrate, the semiconductor device manufacturing apparatus comprising:
a reaction gas introduction unit configured to introduce reaction gas comprising nitrogen gas and rare gas into a substrate process chamber;
a plasma generating unit configured to ionize the reaction gas into plasma;
a substrate stage installed inside the process chamber for placing a substrate on the substrate stage;
a substrate heating unit configured to heat a substrate; and
a control unit configured to control an operation of introducing reaction gas comprising nitrogen gas and rare gas after a substrate comprising a high-k gate insulating film is carried into the process chamber, an operation of ionizing the introduced reaction gas into plasma for nitrogenizing the high-k gate insulating film of the substrate, and an operation of stopping introduction of the rare gas.
